(19) United States
(12) Patent Application Publication
(10) Pub. No.: US 2022/0243322 A1
(43) Pub. Date: Aug. 4, 2022

(54) SUBSTRATE PROCESSING APPARATUS

(71) Applicant: ASM IP Holding B.V., Almere (NL)

(72) Inventors: TaeWoong Kim, Jeonju-si (KR); JiHwan Ryu, Gyeonggi-do (KR); YongWoong Jeong, Hwaseong-si (KR); YoungSim Kim, Seongnam-si (KR); YoungMin Kim, Hwaseong-si (KR)

(21) Appl. No.: 17/585,224

(22) Filed: Jan. 26, 2022

Related U.S. Application Data
(60) Provisional application No. 63/143,719, filed on Jan. 29, 2021.

(51) Int. Cl. C23C 16/44; H01J 37/32; C23C 16/458; C23C 16/455

(52) U.S. Cl. CPC C23C 16/4412; H01J 37/32834; H01J 37/32449; H01J 2237/332; C23C 16/45589; C23C 16/45544; C23C 16/4583

(57) ABSTRACT

Provided is a reactor capable of improving the symmetry of the profile of a thin film deposited on a substrate with an asymmetric exhaust structure, wherein a distance between a gas flow control ring (FCR) and an exhaust unit on one side where an exhaust port is located is greater than a distance between the FCR and the exhaust unit on the opposite side of the exhaust port.

### CROSS-REFERENCE TO RELATED APPLICATIONS

This application claims the benefit of and priority to U.S. Provisional Patent Application Ser. No. 63/143,719 filed Jan. 29, 2021, the disclosure of which is hereby incorporated by reference in its entirety.

### BACKGROUND

### 1. Field

One or more embodiments of the disclosure relate to a substrate processing apparatus, and more particularly, to a substrate processing apparatus having an asymmetric exhaust structure in order to improve the symmetry of the profile of a thin film deposited on a substrate.

### 2. Description of the Related Art

As shown in FIG. 1, in a substrate processing apparatus 1 equipped with a plurality of reactors 2, an exhaust port 3 of each reactor 2 is located on an outer wall (in the case of FIG. 1, a sidewall) of the reactor 2, and may be formed to penetrate an outer wall of the substrate processing apparatus 1. As an example, the exhaust port 3 on the reactor 2 may be configured to penetrate perpendicularly a corner surface where two outer walls 4 and 5 of the substrate processing apparatus 1 intersect. One or more of exhaust ports 3 of the plurality of reactors 2 may be connected to each other through common exhaust lines 6 and 7 at the side or bottom of the substrate processing apparatus 1, and may be connected to an exhaust pump 8 via the common exhaust lines 6 and 7. Each reactor 2 may share the exhaust pump 8 through the common exhaust lines 6 and 7, as shown in FIG. 1, and may be connected to a separate exhaust line (not shown) for each reactor and may be connected to respective exhaust pump 8. A residual gas after the reaction in each reactor 2 may be exhausted to the outside through the exhaust port 3, the exhaust lines 6 and 7, and the exhaust pump 8.

However, because the exhaust port 3 is located asymmetrically with respect to the center of the reactor 2, an exhaust flow in the reactor 2 is asymmetric with respect to the center of the reactor 2, which is the main cause of the asymmetry of a deposition profile of a thin film on a substrate (an asymmetric film profile).

FIG. 2 shows that the exhaust port 3 is asymmetrically arranged with respect to the center of the reactor 2, so that the thickness profile of the thin film on the substrate is asymmetric.

In general, in one reactor 2, the exhaust flow near the exhaust port 3 is faster than the exhaust flow at the opposite side of the exhaust port 3. Accordingly, the thickness (−) of the thin film on the substrate near the exhaust port 3 is less than the thickness (+) of the thin film on the substrate at a position far from the exhaust port 3. Also, due to a limited purge period performed after a deposition/reactive gas supply period, a relatively large amount of deposition gas/reactive gas accumulates in a portion of a reaction space far from the exhaust port 3 compared to a portion close to the exhaust port 3. Accordingly, a thin film is deposited thicker in the portion far from the exhaust port 3. Such an asymmetric thin film thickness may cause a process failure in a subsequent process or deteriorate compatibility with the subsequent process.

### SUMMARY

One or more embodiments include a substrate processing apparatus capable of reducing the asymmetry of a deposited film profile due to the asymmetry of an exhaust flow.

One or more embodiments include a substrate processing apparatus having an asymmetric exhaust structure to improve the symmetry of the thickness profile of a thin film deposited on a substrate.

Additional aspects will be set forth in part in the description which follows and, in part, will be apparent from the description, or may be learned by practice of the presented embodiments of the disclosure.

According to one or more embodiments, a reactor includes: an upper body including a gas supply unit and an exhaust unit; a substrate support device; and an inner ring surrounding the substrate support device and arranged between the substrate support device and a sidewall of the reactor, and a reaction space is formed between the gas supply unit and the substrate support device, wherein the exhaust unit includes: an exhaust port located on a first side of the reactor; an exhaust duct configured to provide an exhaust space therein; an exhaust hole connecting the exhaust space of the exhaust duct to the exhaust port and arranged inside the upper body; and an exhaust channel extending from the reaction space to the exhaust port through the inner space of the exhaust duct and the exhaust hole, wherein a first step toward the reaction space is formed below the upper body, the inner ring is seated on the first step, a vertical distance between the exhaust duct and the inner ring on the first side is greater than a vertical distance between the exhaust duct and the inner ring on the second side, and the second side is opposite to the first side with respect to the center of the upper body.

According to an example of the reactor, a vertical distance between the exhaust duct and the inner ring on the first side may be greater than a vertical distance between the substrate support device and the gas supply unit.

According to another example of the reactor, a vertical distance between the exhaust duct and the inner ring on the second side may be greater than a vertical distance between the substrate support device and the gas supply unit.

According to another example of the reactor, a vertical distance between the exhaust duct and the inner ring on the second side may be less than a vertical distance between the substrate support device and the gas supply unit.

According to another example of the reactor, during an exhaust operation, a gas exhaust flow at the first side may be faster than a gas exhaust flow at the second side.

According to another example of the reactor, during an exhaust operation, an exhaust pressure gradient may be strengthened from the second side to the first side within the reaction space.

According to another example of the reactor, a gas exhaust flow rate may be adjusted by adjusting at least one of a vertical distance between the exhaust duct and the inner ring on the first side and a vertical distance between the exhaust duct and the inner ring on the second side.

According to a further example of the reactor, the uniformity or symmetry of the thickness of a thin film deposited on a substrate may be controlled by adjusting at least one of a vertical distance between the exhaust duct and the inner ring on the first side and a vertical distance between the exhaust duct and the inner ring on the second side.

According to another example of the reactor, an upper surface of the inner ring is inclined to be higher at the second side than at the first side, and a gas exhaust flow rate may be adjusted by adjusting an inclination of the upper surface of the inner ring.

According to a further example of the reactor, an outer ring may be seated on a first step below the upper body, a second step toward the reaction space may be formed in the outer ring, and the inner ring may be seated on a second step of the outer ring.

According to a further example of the reactor, a vertical distance between the exhaust duct and the outer ring at the second side may be greater than a vertical distance between the exhaust duct and the inner ring at the second side.

According to a further example of the reactor, a vertical distance between the exhaust duct and the outer ring at the first side may be greater than a vertical distance between the exhaust duct and the inner ring at the first side.

According to another example of the reactor, an exhaust channel inside the upper body may be formed to surround the reaction space.

According to another example of the reactor, the exhaust channel may have a greater width at the first side than at the second side.

According to one or more embodiments, a gas flow control ring (FCR) includes a structure in which an upper surface of the gas flow control ring is higher at the second side than at the first side and is inclined from a second side toward a first side, and the second side is opposite to the first side with respect to the center of the gas flow control ring.

According to another example of the gas flow control ring, the gas flow control ring is seated in a reactor to surround a substrate support device, and a gas exhaust flow rate in the reactor may be adjusted according to an inclination of the upper surface of the gas flow control ring.

According to one or more embodiments, a substrate processing apparatus includes an outer chamber providing an inner space; at least one reactor arranged in the inner space, which is one of the aforementioned reactors; a deposition gas source configured to supply a deposition gas to the at least one reactor; a reactive gas source configured to supply a reactive gas to the at least one reactor; and at least one exhaust pump connected to an exhaust port of the at least one reactor through an exhaust line.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a top view of a substrate processing apparatus including a plurality of reactors;

FIG. 2 is a view illustrating that the thickness of a thin film deposited on a substrate in the substrate processing apparatus of FIG. 1 has an asymmetric profile;

FIG. 3 is a view of a conventional reactor;

FIG. 4 is a view of a reactor according to embodiments of the present disclosure;

FIG. 5 is a view of a reactor equipped with an outer ring according to other embodiments of the present disclosure;

FIG. 6 is a cross-sectional view of an inner ring according to the present disclosure;

FIGS. 7A and 7B are views of an exhaust flow on a substrate in each of the reactors of FIGS. 3 and 4;

FIG. 8 is a view illustrating the thickness and uniformity of a SiO₂ thin film deposited in the conventional reactor and a reactor according to an embodiment respectively; and

FIG. 9 is a view of a substrate processing apparatus according to an embodiment.

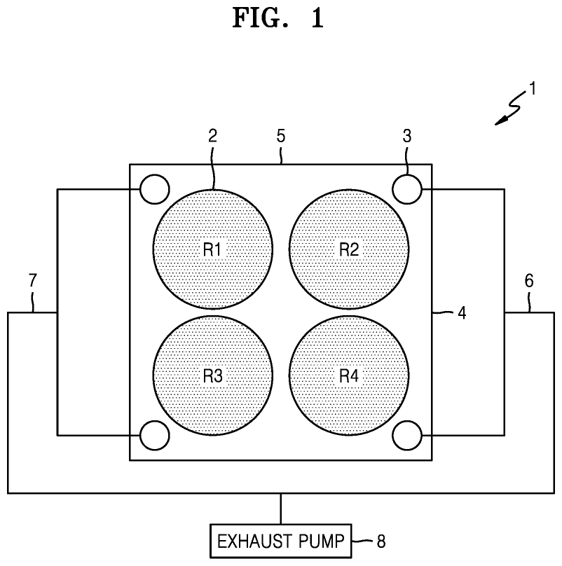

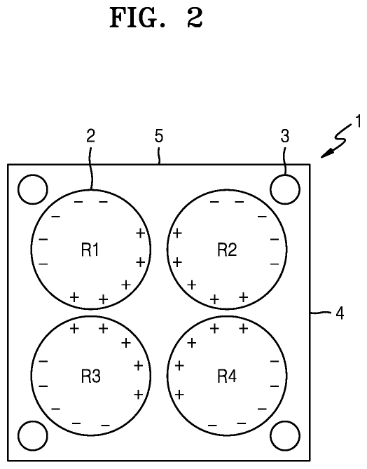

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments of the disclosure will be described in detail with reference to the accompanying drawings.

In this regard, the present embodiments may have different forms and should not be construed as being limited to the descriptions set forth herein. Rather, these embodiments are provided so that the present disclosure will be thorough and complete, and will fully convey the scope of the present disclosure to one of ordinary skill in the art.

The terminology used herein is for describing particular embodiments and is not intended to limit the disclosure. As used herein, the singular forms “a”, “an”, and “the” are intended to include the plural forms as well, unless the context clearly indicates otherwise. It will be further understood that the terms “includes”, “comprises” and/or “including”, “comprising” used herein specify the presence of stated features, integers, steps, processes, members, components, and/or groups thereof, but do not preclude the presence or addition of one or more other features, integers, steps, processes, members, components, and/or groups thereof. As used herein, the term “and/or” includes any and all combinations of one or more of the associated listed items.

It will be understood that, although the terms first, second, etc. may be used herein to describe various members, components, regions, layers, and/or sections, these members, components, regions, layers, and/or sections should not be limited by these terms. These terms do not denote any order, quantity, or importance, but rather are only used to distinguish one component, region, layer, and/or section from another component, region, layer, and/or section. Thus, a first member, component, region, layer, or section discussed below could be termed a second member, component, region, layer, or section without departing from the teachings of embodiments.

Embodiments of the disclosure will be described hereinafter with reference to the drawings in which embodiments of the disclosure are schematically illustrated. In the drawings, variations from the illustrated shapes may be expected because of, for example, manufacturing techniques and/or tolerances. Thus, the embodiments of the disclosure should not be construed as being limited to the particular shapes of regions illustrated herein but may include deviations in shapes that result, for example, from manufacturing processes.

Although a deposition device of a semiconductor or a display substrate is described herein as the substrate processing apparatus, it is to be understood that the disclosure is not limited thereto. The substrate processing apparatus may be any device necessary for performing deposition of a material for forming a thin film, and may refer to a device in which a raw material for etching or polishing the material is uniformly supplied. Hereinafter, for convenience of description, it is assumed that the substrate processing apparatus is a semiconductor deposition device.

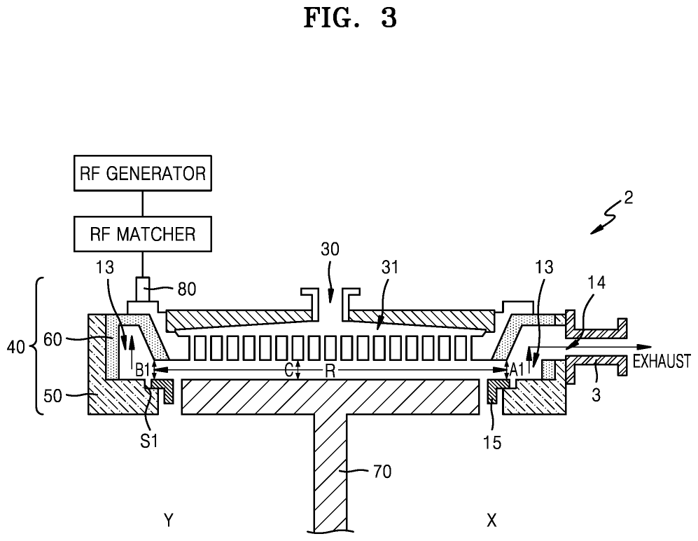

FIG. 3 is a view of a conventional reactor 2. The reactor 2 may be arranged inside a chamber of the substrate processing apparatus.

The reactor 2 according to an embodiment may include an upper body 40. In addition, the reactor 2 may include a substrate support device 70, and an inner ring 15 surrounding the substrate support device 70 and arranged between the substrate support device 70 and a sidewall 50 of the reactor 2 in an inner space of the reactor 2.

The reactor 2 may be a reactor in which an atomic layer deposition (ALD) or chemical vapor deposition (CVD) process is performed.

The upper body 40 of the reactor 2 may include a gas inlet unit 30, a gas supply unit 31, and an exhaust unit.

The gas supply unit 31 may be implemented in, for example, a lateral flow-type assembly structure or a showerhead-type assembly structure. The gas supply unit 31 may form a reaction space R together with the substrate support device 70.

A base of the gas supply unit 31 may include a plurality of gas supply holes formed (e.g., in a vertical direction) to eject a process gas. The gas supply unit 31 includes a metal material and may serve as an electrode during a plasma process. During the plasma process, a high frequency (RF) power source may be electrically connected to the gas supply unit 31 functioning as one electrode. In more detail, an RF rod 80 connected to the RF power source may pass through a reactor wall and be connected to the gas supply unit 31. In this case, the substrate support device 70 may function as the other electrode.

The exhaust unit may include an exhaust port 3, an exhaust duct 60, an exhaust hole 14, and an exhaust channel.

The exhaust port 3 may be located on one side of the reactor 2 according to an exhaust method, and may be upward exhaust or downward exhaust or side exhaust. For example, as shown in FIG. 3, the exhaust port 3 may be located on the side of the reactor 2. It should be noted that although a lateral exhaust structure is used as an example of the exhaust method described herein, the disclosure is not limited thereto. The exhaust port 3 may be located on an upper surface of the reactor 2 for upward exhaust, or may be located below the reactor 2 for downward exhaust. Hereinafter, for convenience, it will be described on the premise that side exhaust of the reactor 2 is used.

A first step S1 toward the reaction space R may be formed below the upper body 40. The first step S1 may have an upper surface, a lower surface, and a side surface connecting the upper surface to the lower surface. The exhaust duct 60 may be seated on the upper surface of the first step S1. The gas supply unit 31 may be provided in an inner space surrounded by the exhaust duct 60.

The inside of the exhaust duct 60 may provide an exhaust space 13. An exhaust hole 14 may be formed on one side (in more detail, on the side where the exhaust port 3 is located) of the exhaust duct 60 and in the upper body 40 of the reactor 2. In more detail, the exhaust hole 14 may be formed in the sidewall 50 of the reactor. The exhaust hole 14 may be configured to connect the exhaust space 13 of the exhaust duct 60 with the exhaust port 3.

The exhaust channel includes the exhaust space 13 and the exhaust hole 14 of the exhaust duct 60, and may be formed continuously inside the exhaust duct 60 and the reactor sidewall 50. The exhaust channel may extend from the reaction space R to the exhaust port 3 through the exhaust space 13 and the exhaust hole 14, thereby connecting the reaction space R to the exhaust port 3. The exhaust channel may be formed to surround the reaction space R, and thus, a reactive gas in the reaction space R may be relatively evenly exhausted.

The substrate support device 70 may include a susceptor body (not shown) supporting a substrate and a heater heating the substrate supported by the susceptor body. For loading/unloading of a substrate, the substrate support device 70 may be configured to be vertically movable by being connected to a driving motor (not shown) provided to one side of the substrate support device 70. In more detail, during processing of the substrate, the substrate support device 70, on which the substrate is mounted, may be raised to maintain a distance between the gas supply unit 31 and the substrate at a processable distance. When the substrate support device 70 is raised, the substrate support device 70 may form the reaction space R with the gas supply unit 31 and the upper body 40. When the substrate process is completed, the substrate support device 70 may descend to a substrate unloading position and then unload the substrate.

The inner ring 15 may be seated on the first step S1 formed below the upper body 40. In more detail, the inner ring 15 may be seated on a lower surface of the first step S1. The inner ring 15 may generally have a circular ring shape, but is not limited thereto. The inner ring 15 may be fixed or movable with respect to the upper body 40. The inner ring 15 may be a gas flow control ring (FCR). The inner ring 15 may control a pressure balance between the reaction space R and a lower space of the substrate support device 70 by adjusting the width of a gap between the first step S1 of the upper body 40 and the substrate support device 70, and may control an exhaust flow rate by adjusting an exhaust channel width between the inner ring 15 and a lower surface of the exhaust duct 60.

According to further embodiments, the inner ring 15 may further include a stopper at the bottom. The stopper may prevent excessive movement of the inner ring 15 toward the reactor wall 50. The stopper may be arranged on a lower surface of the inner ring 15.

In FIG. 3, vertical distances A1 and B1 between the lower surface of the exhaust duct 60 and the inner ring 15 are constant throughout a circumference of the inner ring 15. Therefore, the vertical distance A1 between the lower surface of the exhaust duct 60 and the inner ring 15 at a first side X where the exhaust port 3 is located may be equal to the vertical distance B1 between the lower surface of the exhaust duct 60 and the inner ring 15 at a second side Y opposite the first side X with respect to the center of the reactor 2. That is, in the case of the reactor 2 of FIG. 3, the vertical distance A1 between the lower surface of the exhaust duct 60 and the inner ring 15 on the side closest to the exhaust port 3 may be equal to the vertical distance B1 between the lower surface of the exhaust duct 60 and the inner ring 15 on the side farthest from the exhaust port 3. In addition, a vertical distance between the lower surface of the exhaust duct 60 and the inner ring 15 may be the same as a vertical distance C between the substrate support device 70 and the gas supply unit 31.

During a deposition/reactive gas supply operation, a process gas introduced through the gas inlet unit 30 may be supplied to the reaction space R and the substrate through the gas supply unit 31. The process gas supplied on the substrate may undergo a chemical reaction with the substrate or a chemical reaction between gases, and then deposit a thin film or etch a thin film on the substrate.

Thereafter, in the reaction space R, a residual gas or un-reacted gas remaining after the chemical reaction with the substrate may be exhausted to the outside through an exhaust channel (i.e., the exhaust space 13 and the exhaust hole 14), the exhaust port 3 and an exhaust pump (not shown) connected to the exhaust port 3 during an exhaust operation.

However, as described above, because the exhaust port 3 is located asymmetrically with respect to the center of the reactor 2, an exhaust flow in the reactor 2 is asymmetric with respect to the center of the reactor 2. In more detail, because the exhaust port 3 is located on the first side X of the reactor 2, a gas exhaust rate at the side X close to the exhaust port 3 is greater than a gas exhaust rate at the side Y far from the exhaust port 3. Due to the difference in the gas exhaust rates at the first side X and the second side Y, during the exhaust operation, the entire gas exhaust direction in the reaction space R may be a direction from the second side Y to the first side X. However, in a substrate processing process in which deposition/reactive gas supply, interruption, and exhaust are repeated, as shown in FIG. 3, due to the difference in the physical distance to the exhaust port 3, gas may accumulate on the second side Y in the reaction space R compared to the first side X in the reaction space R, which may be a major cause of the asymmetry of a deposition profile of a thin film on the substrate (an asymmetric film profile). In particular, as in an atomic layer deposition method, the faster the cycle of gas supply, interruption, and exhaust, the worse this phenomenon.

Therefore, there is a need for a method of mitigating the accumulation of gas in the reaction space R on the side Y far from the exhaust port 3.

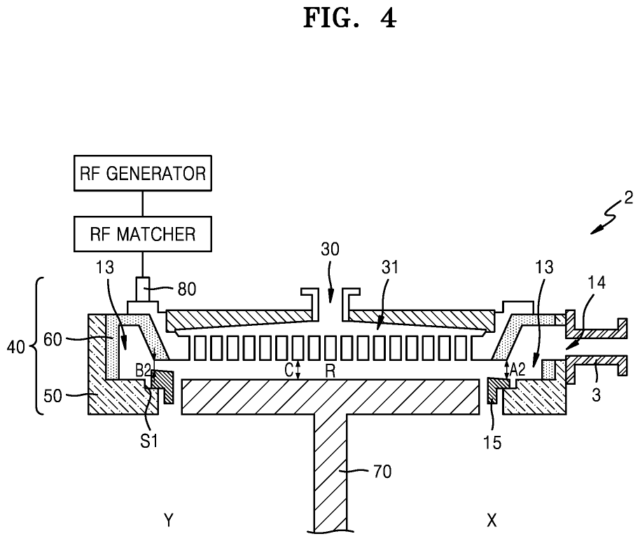

FIG. 4 is a view of a reactor according to embodiments of the present disclosure. Hereinafter, repeated descriptions of the embodiments will not be given herein.

Referring to FIG. 4, the vertical distance C between the substrate support device 70 and the gas supply unit 31 is the same throughout the substrate support device 70. However, unlike FIG. 3, a vertical distance between the inner ring 15 and a lower surface of the exhaust duct 60 may be different depending on the position. For example, an upper surface of the inner ring 15 of FIG. 4 may be configured to be higher on the second side Y than on the first side X. That is, the inner ring 15 may be configured to have a lower height on the first side X close to the exhaust port 3. Accordingly, a vertical distance A2 between the lower surface of the exhaust duct 60 and the inner ring 15 on the first side X may be longer than a vertical distance B2 between the lower surface of the exhaust duct 60 and the inner ring 15 on the second side Y. For example, A2 may be 1.5 mm and B2 may be 1.0 mm.

Also, in an embodiment, the vertical distance A2 between the lower surface of the exhaust duct 60 and the inner ring 15 on the first side X of FIG. 4 may be greater than the vertical distance A1 between the lower surface of the exhaust duct 60 and the inner ring 15 on the first side X of FIG. 3. That is, the vertical distance A2 between the lower surface of the exhaust duct 60 and the inner ring 15 on the first side X may be greater than the vertical distance C between the substrate support device 70 and the gas supply unit 31.

In a further embodiment, the vertical distance B2 between the lower surface of the exhaust duct 60 and the inner ring 15 at the second side Y of FIG. 4 may be less than the vertical distance B1 between the lower surface of the exhaust duct 60 and the inner ring 15 at the second side Y of FIG. 3. That is, the vertical distance B2 between the lower surface of the exhaust duct 60 and the inner ring 15 on the second side Y may be less than the vertical distance C between the substrate support device 70 and the gas supply unit 31.

Because the inner ring 15 has such a structure, on the first side X close to the exhaust port 3, the width of an inlet of an exhaust channel, where the reaction space R and the exhaust space 13 of the exhaust duct 60 meet, becomes wider. Accordingly, the gas exhaust rate at the first side X increases. On the other hand, the width of an inlet of the exhaust channel where the reaction space R and the exhaust space 13 of the exhaust duct 60 meet at the second side Y far from the exhaust port 3 becomes narrower. Accordingly, in the second side Y, a physical barrier (in this case, the inner ring 15) on an exhaust flow path from the reaction space R to the exhaust space 13 becomes higher, so that the exhaust rate in a direction from the second side to the first side becomes faster.

Due to the difference in the gas exhaust rates at the first side X and the second side Y, during the exhaust operation, a gas exhaust direction in the reaction space R may be the direction from the second side Y to the first side X. However, as the gas exhaust rate at the first side X is greater than that in the embodiment of FIG. 3, in FIG. 4, a gas exhaust rate from the second side Y to the first side X in the reaction space R may be greater than that of FIG. 3. Accordingly, in the reaction space R, the accumulation of gas without being exhausted from the second side Y farthest from the exhaust port 3 may be alleviated, thereby improving the symmetry of a deposition profile of a thin film on a substrate.

In a variant embodiment, the vertical distance B2 between the lower surface of the exhaust duct 60 and the inner ring 15 at the second side Y of FIG. 4 may be less than the vertical distance A2 between the lower surface of the exhaust duct 60 and the inner ring 15 at the first side X, and may be greater than the vertical distance C between the substrate support device 70 and the gas supply unit 31. Accordingly, the physical barrier (in this case, the inner ring 15) on the exhaust flow path from the reaction space R to the exhaust space 13 at both the first side X and the second side Y becomes lower. Therefore, the gas exhaust rate may be increased in both the first side X and the second side Y.

In a further embodiment, the gas exhaust rate may be adjusted by adjusting at least one of the vertical distance A2 between the exhaust duct 60 and the inner ring 15 on the first side X and the vertical distance B2 between the exhaust duct 60 and the inner ring 15 at the second side Y. In a further embodiment, the uniformity of the thickness of a thin film deposited on a substrate or the symmetry of a deposition profile may be controlled by adjusting at least one of the vertical distance A2 between the exhaust duct 60 and the inner ring 15 on the first side X and the vertical distance B2 between the exhaust duct 60 and the inner ring 15 at the second side Y.

For example, in order to increase a gas exhaust flow rate near the exhaust port 3, the thickness of the inner ring 15 on the first side X is made thin, so that the vertical distance A2 between the lower surface of the exhaust duct 60 and the inner ring 15 on the first side X may be greater than the vertical distance C between the substrate support device 70 and the gas supply unit 31. Thus, when a residual gas in the reaction space R on the substrate support device 70 is exhausted to the exhaust port 3, the physical barrier (in this case, the inner ring 15) on the exhaust channel may be lowered, and the residual gas in the reaction space R may be exhausted more quickly to the exhaust port 3 through the exhaust channel on the first side. Accordingly, the accumulation of gas without being exhausted from the second side Y may be alleviated and the exhaust rates from the second side Y to the first side X may be sped up and a thicker thin film may be prevented from being deposited on the second side Y compared to the first side X.

Also, in order to further accelerate an exhaust flow rate of the residual gas in the reaction space R to the exhaust port 3, the thickness of the inner ring 15 on the second side Y is made thin, so that the vertical distance B2 between the lower surface of the exhaust duct 60 and the inner ring 15 on the second side Y may be less than the vertical distance C between the substrate support device 70 and the gas supply unit 31. As the physical barrier on the second side Y is higher than that on the first side X in the exhaust of gas to the exhaust duct 60, during the same exhaust time, the amount of exhaust exhausted from the second side Y to the exhaust space 13 may decrease compared to the first side X, and the amount of gas remaining in the second side Y may further increase. Accordingly, by lowering the physical barrier of exhaust at the first side X close to the exhaust port 3 in the reaction space R, an exhaust pressure gradient may be formed in a direction from the second side Y to the first side X in the reaction space R. Accordingly, the exhaust of gas accumulated in the second side Y far from the exhaust port 3 is accelerated to be exhausted more quickly in a direction of the first side X, and the symmetry of a deposition profile of a thin film on the substrate may be improved.

However, on the contrary, the vertical distance B2 between the lower surface of the exhaust duct 60 and the inner ring 15 at the second side Y may be less than the vertical distance A2 between the lower surface of the exhaust duct 60 and the inner ring 15 at the first side X, and may be greater than the vertical distance C between the substrate support device 70 and the gas supply unit 31. Accordingly, the gas exhaust rate may be increased in both the first side X and the second side Y, and the symmetry of a deposition profile of a thin film on the substrate may be improved.

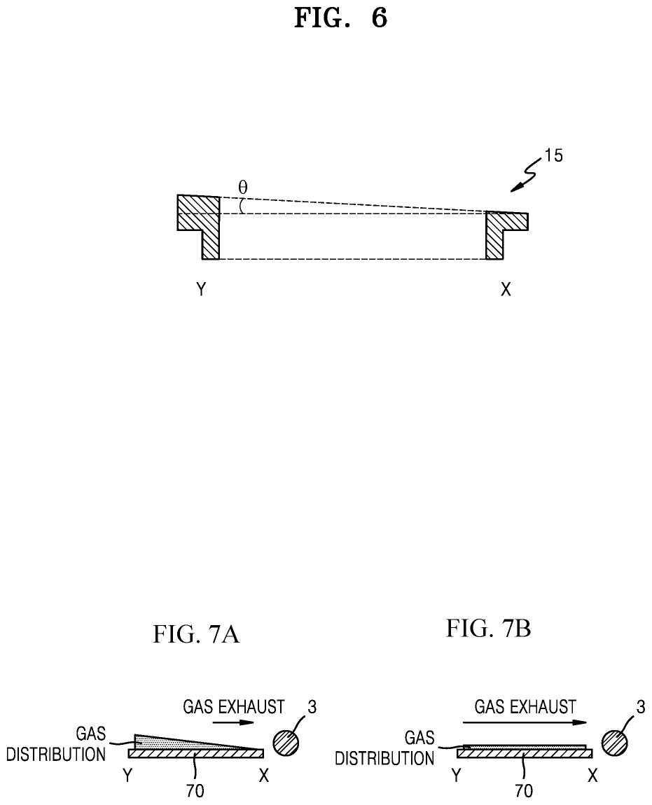

In a further embodiment, as shown in FIG. 6, the upper surface of the inner ring 15 may be inclined from the second side Y toward the first side X to be higher at the second side Y than at the first side X. That is, the upper surface of the inner ring 15 may have a shape inclined toward the exhaust port 3 continuously or gradually. In other words, a distance between the exhaust duct 60 and the upper surface of the inner ring 15 may have a shape that gradually increases toward the exhaust port 3 or, the height (thickness) of the inner ring 15 gradually decreases toward the exhaust port 3. The structure of the inner ring 15 is to control the exhaust rate by adjusting the distance between the inner ring 15 and the exhaust duct 60. Accordingly, the gas exhaust flow rate may be adjusted by adjusting an inclination 8 of the upper surface of the inner ring 15. In more detail, as the inclination 8 of the upper surface of the inner ring 15 increases, an exhaust pressure gradient in a direction from the second side Y to the first side X is strengthened and the exhaust flow rate of the residual gas in the reaction space R may increase. As the inclination 8 of the upper surface of the inner ring 15 decreases, the exhaust flow rate of the residual gas in the reaction space R in a direction from the second side Y to the first side X may decrease.

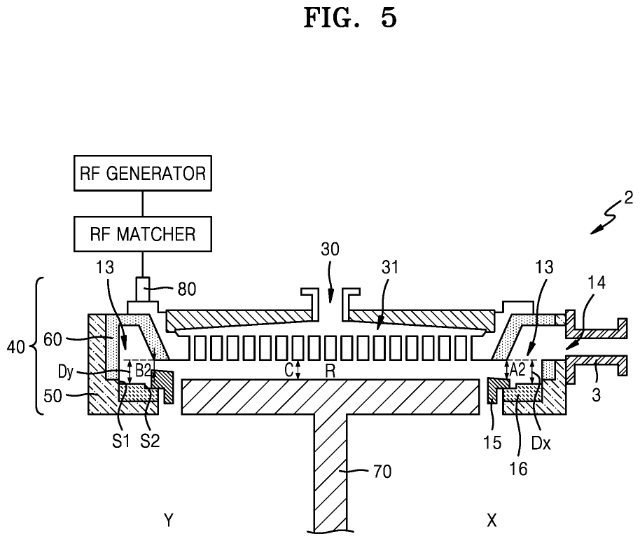

In the embodiments of FIGS. 4 and 5, the exhaust channel may have a greater width in the first side X than in the second side Y. For example, the exhaust space 13 of the exhaust duct 60 may have a greater width as it approaches the exhaust port 3 and may increase the exhaust capacity. Thus, an exhaust flow in a direction of the exhaust port 3 may be strengthened, and the exhaust pressure gradient from the second side Y to the first side X in the reaction space R may be further strengthened. Accordingly, a phenomenon in which the residual gas accumulates on the second side Y may be reduced, and the symmetry of the thickness of a deposited film may be improved.

FIG. 5 is a view of a reactor equipped with an outer ring according to other embodiments of the present disclosure. Hereinafter, repeated descriptions of the embodiments will not be given herein.

In order to further accelerate the exhaust flow rate of the residual gas in the reaction space R to the exhaust port 3, an outer ring 16 may be mounted in addition to the reactor configuration of FIG. 4.

In more detail, the first step S1 toward the reaction space R may be formed below the upper body 40. The first step S1 may have an upper surface, a lower surface, and a side surface connecting the upper surface to the lower surface. The exhaust duct 60 may be seated on the upper surface of the first step S1, and the outer ring 16 may be seated on the lower surface of the first step S1.

In this case, the inner ring 15 may be seated on the outer ring 16. In more detail, a second step S2 toward the reaction space R may be formed on the outer ring 16. The second step S2 may have an upper surface, a lower surface, and a side surface connecting the upper surface to the lower surface. The inner ring 15 may be seated on the second step S2 of the outer ring 16, specifically on the lower surface of the second step S2.

The outer ring 16 may generally have a circular ring shape, but is not limited thereto. The outer ring 16 may be fixed to the upper body 16. The outer ring 16 may be an FCR. The outer ring 16 may control an exhaust rate of gas exhausted from the reaction space R to the exhaust space 13 of the exhaust duct 60 by adjusting a vertical distance between the upper surface of the outer ring 16 and the exhaust duct 60.

In FIG. 5, a vertical distance between the lower surface of the exhaust duct 60 and the outer ring 16 may be constant over the entire circumference of the outer ring 16. Therefore, a vertical distance Dx between the lower surface of the exhaust duct 60 and the outer ring 16 at the first side X where the exhaust port 3 is located may be equal to a vertical distance Dy between the lower surface of the exhaust duct 60 and the outer ring 16 at the second side Y.

In order to lower the physical barrier (in this case, the inner ring 15 and the outer ring 16) on the exhaust flow path from the reaction space R to the exhaust space 13 on the first side X, that is, in order to smoothly exhaust the residual gas in the reaction space R on the first side X into the exhaust space 13 of the exhaust duct 60, the vertical distance Dx between the lower surface of the exhaust duct 60 and the outer ring 16 on the first side X may be longer than the vertical distance A2 between the lower surface of the exhaust duct 60 and the inner ring 15 on the first side X. Thus, the width of an exhaust channel on the outer ring 16 on the first side X may be greater, and an exhaust flow to the exhaust port 3 may smoothly proceed.

In order to lower the physical barrier (in this case, the inner ring 15 and the outer ring 16) on the exhaust flow path from the reaction space R to the exhaust space 13 on the second side Y, the vertical distance Dy between the lower surface of the exhaust duct 60 and the outer ring 16 on the second side Y may be longer than the vertical distance B2 between the lower surface of the exhaust duct 60 and the inner ring 15 on the second side Y. Thus, the width of an exhaust channel on the outer ring 16 on the second side Y may be greater, and the exhaust flow to the exhaust port 3 may smoothly proceed.

As described with reference to FIGS. 4 and 5, according to embodiments of the present disclosure, by adjusting the vertical distance between the inner ring 15 and the lower surface of the exhaust duct 60, an exhaust flow rate (from the second side Y to the first side X) in the reaction space R on the substrate support device 70 may be controlled. In addition, by adjusting the vertical distance between the outer ring 16 and the lower surface of the exhaust duct 60, the respective exhaust flow rates from the upper space of the inner ring 15 to the exhaust space 13 on the first side X and the second side Y may be controlled. As such, according to embodiments of the present disclosure, by adjusting the respective distances between the inner ring 15 and the outer ring 16 surrounding the substrate support device 70 and the exhaust duct 60, the exhaust flow rate may be controlled, and the symmetry of a thickness of a deposited film may be controlled. Further, it is possible to control the exhaust flow rate by maintaining the respective distances between the inner ring 15 and the outer ring 16 and the exhaust duct 60 asymmetrically. In spite of the asymmetry of the exhaust structure, a thin film having a symmetrical thickness profile may be deposited on the substrate. Unlike the prior art of changing the shape, number, or arrangement structure of exhaust holes 14 in order to improve a symmetric deposition profile of the deposited film, the disclosure may solve the problem that a thin film is asymmetrically deposited by only modifying the shape of the inner ring 15. That is, using the disclosure, it is possible to solve a problem in that a thin film is symmetrically deposited with a minimum cost and time while minimizing structural changes of a substrate processing apparatus compared to the prior art.

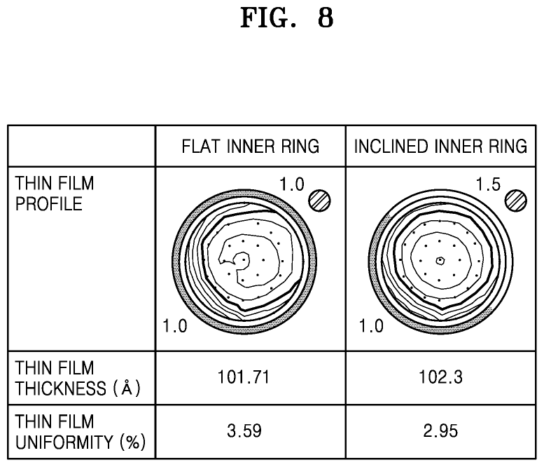

FIGS. 7 and 8 show results obtained by maintaining a distance between an inner ring and an exhaust duct asymmetrically.

FIGS. 7A and 7B show gas distribution or gas accumulation on substrates in the reactors of FIGS. 3 and 4, respectively. That is, FIG. 7A shows the distribution of a gas exhaust flow on the substrate support device 70 in the reactor 2 in which a vertical distance between the inner ring 15 and the exhaust duct 60 is uniform, and FIG. 7B shows the distribution of a gas exhaust flow on the substrate support device 70 in the reactor 2 where the vertical distance between the inner ring 15 and the exhaust duct 60 becomes longer as it is closer to the exhaust port 3.

In general, as in the case of FIG. 7A, a vertical distance between an inner ring and an exhaust duct is uniform, so that a gas exhaust rate from the second side Y to the first side X in a reaction space is not fast and gas is relatively more accumulated on the second side Y than on the first side X. For an ALD process, gas supply and purge operations are repeated so that gas that has not been exhausted remains and accumulates in the reaction space located far from the exhaust port 3 during an exhaust time, that is, a limited purge time. This may be a major cause of the asymmetry of a deposition profile of a thin film on the substrate (an asymmetric film profile).

In the case of FIG. 7B, a distance between the inner ring and the exhaust duct on the first side X close to the exhaust port 3 is greater, and thus, the gas exhaust rate at the first side X becomes faster. On the other hand, the distance between the inner ring and the exhaust duct at the second side Y far from the exhaust port 3 is less, and thus, an exhaust pressure gradient in a direction from the second side Y to the first side X is strengthened and the exhaust flow becomes faster. In the case of FIG. 7B, the gas exhaust rate at the first side X is faster compared to the case of FIG. 7A, and the gas exhaust rate from the second side Y to the first side X in the reaction space may be faster than that of FIG. 7A and the amount of remaining gas on the second side Y is almost the same as that on the first side X. Accordingly, despite a limited purge time, gas at the second side Y farthest from the exhaust port 3 in the reaction space does not accumulate, and rapid exhaust through the exhaust duct on the first side X may be possible. As such, by adjusting the distance between the inner ring and the exhaust duct, exhaust efficiency may be increased, and a phenomenon in which gas is accumulated on the second side Y may be alleviated.

FIG. 8 shows the thickness and uniformity of SiO₂ thin films deposited in the reactor of FIG. 3 and the reactor of FIG. 4.

In the case of the reactor of FIG. 3, an inner ring having a flat top surface is used, and a distance between the inner ring and an exhaust duct is constant at 1.0 mm. In the case of the reactor of FIG. 4, an inner ring with an inclined top surface is used, a distance between the inner ring and an exhaust duct on the side where the exhaust port 3 is located is 1.5 mm, and a distance between the inner ring and the exhaust duct on the opposite side of the exhaust port 3 is 1.0 mm, which are different from each other.

It can be seen that the uniformity of the SiO₂ thin film deposited in the reactor of FIG. 3 is 3.59%, and the SiO₂ thin film has an asymmetrical profile in which the thin film thickness becomes thicker as it is located farther from the exhaust port 3.

However, it can be seen that the uniformity of the SiO₂ thin film deposited in the reactor of FIG. 4 is 2.95%, and the SiO₂ thin film profile is a concentric circle close to a circular shape. That is, in the use of the reactor of FIG. 4 (i.e., the reactor having an asymmetric exhaust structure), the problem that the farther away from the exhaust port 3, the thicker the thin film is deposited on the substrate, and the closer to the exhaust port 3, the thinner the thin film is deposited on the substrate can be reduced, and thin film uniformity/symmetry is improved compared to the reactor of FIG. 3.

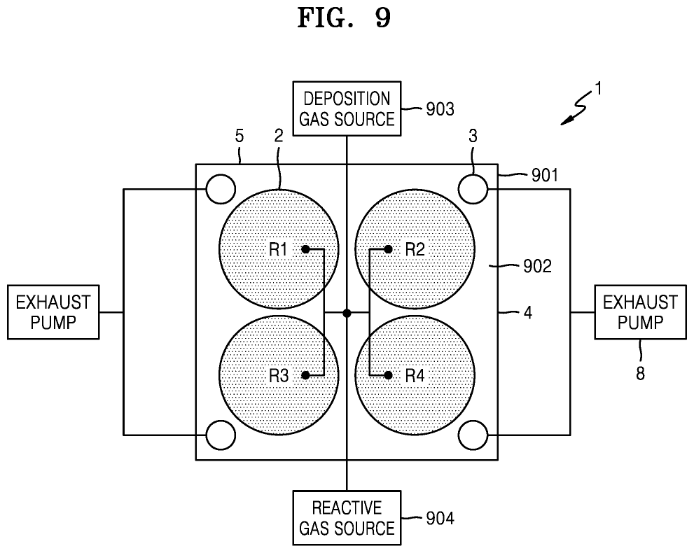

FIG. 9 is a view of the substrate processing apparatus 1 according to an embodiment.

Referring to FIG. 9, the substrate processing apparatus 1 may include an outer chamber 901 providing an inner space 902, at least one reactor 2 arranged in the inner space 902, a deposition gas source 903, a reactive gas source 904, and an exhaust pump 8. The reactor 2 may be the reactor 2 according to an embodiment described above with reference to FIGS. 4 and 5. In particular, the substrate processing apparatus 1 may increase productivity suitable for mass production by providing at least two or more reactors 2. In the substrate processing apparatus 1 equipped with the plurality of reactors 2, the exhaust port 3 of each reactor 2 is located on an outer wall of the reactor 2 and may be formed to pass through an outer wall of the substrate processing apparatus 1. For example, as shown in FIG. 9, the exhaust port 3 on the reactor 2 may be configured to penetrate perpendicularly an edge surface where the two outer walls 4 and 5 of the substrate processing apparatus 1 intersect.

A substrate transfer arm (not shown) capable of rotation and elevation may be provided between four reactors 2 shown in FIG. 9, that is, in the center of the outer chamber 901, thereby allowing substrate loading and unloading between the reactors 2.

According to FIG. 9, at least one reactor 2 may be configured to receive a deposition gas from the deposition gas source 903 and to receive a reactive gas from the reactive gas source 904. Further, the exhaust port 3 of the at least one reactor 2 may be connected to the exhaust pump 8 via an exhaust line at the side or at the bottom. That is, the reactor 2 may be configured such that an exhaust gas discharged through the exhaust port 3 of the at least one reactor 2 is exhausted through the exhaust line connected to the exhaust pump 8. At this time, the at least one reactor 2 may share the exhaust line connecting the exhaust pump 8 to the reactor 2, the deposition gas source 903 and the reactive gas source 904 with at least one other reactor. Thus, degrees of freedom may increase when designing the substrate processing apparatus 1, and deposition processes may be efficiently managed. However, the method, performed by the at least one reactor 2, of sharing the exhaust pump 8, the deposition gas source 903, and the reactive gas source 904 is not limited to FIG. 9, and the substrate processing apparatus 1 may use any other sharing method to improve productivity and efficiency of the substrate processing apparatus 1

According to an embodiment, by providing a substrate processing apparatus having an asymmetric reactor structure, particularly an asymmetric exhaust structure, it is possible to improve the symmetry of the profile of a thin film deposited on a substrate.

According to an embodiment, by changing the shape of a gas flow control ring, the symmetry of the profile of a thin film deposited on a substrate may be improved.

According to an embodiment, the symmetry of a thin film profile may be improved with a minimum cost, time and change of the substrate processing apparatus, compared to the conventional one.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A reactor comprising:
an upper body including a gas supply unit and an exhaust unit;
a substrate support device; and
an inner ring surrounding the substrate support device and arranged between the substrate support device and a sidewall of the reactor, and
a reaction space is formed between the gas supply unit and the substrate support device,
wherein the exhaust unit comprises:
an exhaust port located on a first side of the reactor;
an exhaust duct configured to provide an exhaust space therein;
an exhaust hole connecting the exhaust space of the exhaust duct to the exhaust port and arranged inside the upper body; and
an exhaust channel extending from the reaction space to the exhaust port through the inner space of the exhaust duct and the exhaust hole,
wherein a first step toward the reaction space is formed below the upper body,
the inner ring is seated on the first step,
a vertical distance between the exhaust duct and the inner ring on the first side is greater than a vertical distance between the exhaust duct and the inner ring on the second side, and
the second side is opposite to the first side with respect to the center of the upper body.

2. The reactor of claim 1, wherein a vertical distance between the exhaust duct and the inner ring on the first side is greater than a vertical distance between the substrate support device and the gas supply unit.

3. The reactor of claim 1, wherein a vertical distance between the exhaust duct and the inner ring on the second side is greater than a vertical distance between the substrate support device and the gas supply unit.

4. The reactor of claim 1, wherein a vertical distance between the exhaust duct and the inner ring on the second side is less than a vertical distance between the substrate support device and the gas supply unit.

5. The reactor of claim 1, wherein a gas exhaust flow at the first side is faster than a gas exhaust flow at the second side during an exhaust operation.

6. The reactor of claim 1, wherein an exhaust pressure gradient is strengthened from the second side to the first side in the reaction space during an exhaust operation.

7. The reactor of claim 1, wherein a gas exhaust flow rate is adjusted by adjusting at least one of a vertical distance between the exhaust duct and the inner ring on the first side and a vertical distance between the exhaust duct and the inner ring on the second side.

8. The reactor of claim 7, wherein the uniformity or symmetry of the thickness of a thin film deposited on a substrate is controlled by adjusting at least one of the vertical distance between the exhaust duct and the inner ring on the first side and the vertical distance between the exhaust duct and the inner ring on the second side.

9. The reactor of claim 1, wherein
an upper surface of the inner ring is inclined to be higher at the second side than at the first side, and
a gas exhaust flow rate is adjusted by adjusting an inclination of the upper surface of the inner ring.

10. The reactor of claim 1, wherein
an outer ring is seated on a first step below the upper body,
a second step toward the reaction space is formed in the outer ring, and
the inner ring is seated on the second step of the outer ring.

11. The reactor of claim 10, wherein a vertical distance between the exhaust duct and the outer ring at the second side is greater than a vertical distance between the exhaust duct and the inner ring at the second side.

12. The reactor of claim 10, wherein a vertical distance between the exhaust duct and the outer ring at the first side is greater than a vertical distance between the exhaust duct and the inner ring at the first side.

13. The reactor of claim 1, wherein an exhaust channel inside the upper body is formed to surround the reaction space.

14. The reactor of claim 13, wherein the exhaust channel has a greater width at the first side than at the second side.

15. A gas flow control ring,
wherein an upper surface of the gas flow control ring is configured to be inclined from a second side toward a first side such that the upper surface is higher at the second side than at the first side, and
the second side is opposite to the first side with respect to the center of the gas flow control ring.

16. The gas flow control ring of claim 15,
wherein the gas flow control ring is seated in a reactor so as to surround a substrate support device, and
a gas exhaust flow rate in the reactor is adjusted according to an inclination of the upper surface of the gas flow control ring.

17. A substrate processing apparatus comprising:
an outer chamber providing an inner space;
at least one reactor according to claim 1, and arranged in the inner space;
a deposition gas source configured to supply a deposition gas to the at least one reactor;
a reactive gas source configured to supply a reactive gas to the at least one reactor; and
at least one exhaust pump connected to an exhaust port of the at least one reactor through an exhaust line.
